(19) United States
(12) Patent Application Publication
(10) Pub. No.: US 2018/0213679 A1
(43) Pub. Date: Jul. 26, 2018

(54) HEAT DISSIPATION UNIT

(71) Applicant: ASIA VITAL COMPONENTS CO., LTD., New Taipei City (TW)

(72) Inventor: Chih-Ming Chen, New Taipei City (TW)

(21) Appl. No.: 15/415,877

(22) Filed: Jan. 26, 2017

(51) Int. Cl. H05K 7/20; F28F 3/12; G06F 1/20

(52) U.S. Cl. CPC H05K 7/20336; F28F 3/12; H05K 7/20318; H05K 7/20309; G06F 1/20

(57) ABSTRACT

A heat dissipation unit includes an integrally formed main body. The main body is divided into a first chamber and at least one second chamber. The first and second chambers are adjacent to each other without communicating with each other. A first working fluid is filled in the first chamber. The first chamber is defined as a first heat dissipation section. A second working fluid is filled in the second chamber. The second chamber is defined as a second heat dissipation section. The first heat dissipation section is correspondingly connected with the second heat dissipation section. The heat dissipation unit can achieve both large-area heat dissipation effect and remote-end heat conduction effect. Also, the heat dissipation unit is manufactured at greatly lowered cost.

### BACKGROUND OF THE INVENTION

### 1. Field of the Invention

The present invention relates generally to a heat dissipation unit, and more particularly to a heat dissipation unit, which can achieve both large-area heat dissipation effect and remote-end heat conduction effect. Also, the heat dissipation unit is manufactured at greatly lowered cost.

### 2. Description of the Related Art

Along with the advance of semiconductor technique, the volume of integrated circuit has become smaller and smaller. In order to process more data, the current integrated circuit with the same volume has contained numerous calculation components several times more than the components contained in the conventional integrated circuit. There are more and more calculation components contained in the integrated circuit. Therefore, the execution efficiency of the integrated circuit is higher and higher. As a result, in working, the heat generated by the calculation components is also higher and higher. With a common central processing unit taken as an example, in a full-load working state, the heat generated by the central processing unit is high enough to burn down the entire central processing unit. Therefore, the heat dissipation problem of the integrated circuit has become a very important issue.

The central processing unit and the chips or other electronic components in the electronic apparatus are all heat sources. When the electronic apparatus operates, these heat sources will generate heat. Currently, heat conduction components with good heat dissipation and conduction performance, such as heat pipes, vapor chambers and flat-plate heat pipes are often used to conduct or spread the heat. In these heat dissipation components, the heat pipe serves to conduct heat to a remote end. One end (the heat absorption end) of the heat pipe absorbs the heat to evaporate and convert the internal liquid working fluid into vapor working fluid. The vapor working fluid transfers the heat to the other end (the heat dissipation end) of the heat pipe to achieve the heat conduction effect. With respect to a part with larger heat transfer area, a vapor chamber is selected as the heat dissipation component. One plane face of the vapor chamber is in contact with the heat source to absorb the heat. The heat is then transferred to the other face and dissipated to condense the vapor working fluid.

However, both the conventional heat pipe and vapor chamber are heat dissipation components for solving one single problem, (that is, both the conventional heat pipe and vapor chamber can simply provide heat spreading effect or remote-end heat conduction effect). In other words, the heat pipe or vapor chamber disposed in the electronic apparatus can only dissipate the heat of the heat source by means of conducting the heat to the remote end or spreading the heat, while failing to achieve both the heat spreading and remote-end heat conduction effects. As a result, the heat exchange efficiency is relatively poor.

### SUMMARY OF THE INVENTION

It is therefore a primary object of the present invention to provide a heat dissipation unit, which is manufactured at greatly lowered cost.

It is a further object of the present invention to provide a heat dissipation unit, which can achieve both large-area heat dissipation effect and remote-end heat conduction effect.

To achieve the above and other objects, the heat dissipation unit of the present invention includes an integrally formed main body. The main body has a first chamber and at least one second chamber. The first and second chambers are adjacent to each other without communicating with each other. A first working fluid is filled in the first chamber. The first chamber is defined as a first heat dissipation section. A second working fluid is filled in the second chamber. The second chamber is defined as a second heat dissipation section. The first heat dissipation section is correspondingly connected with the second heat dissipation section. The inner wall of the first chamber has a first capillary structure. The inner wall of the second chamber has a second capillary structure. The first and second capillary structures are not connected with each other.

By means of the structural design of the present invention, the heat dissipation unit can achieve both large-area heat dissipation effect and remote-end heat conduction effect. This improves the shortcoming of the conventional vapor chamber and heat pipe that both the conventional heat pipe and vapor chamber are heat dissipation components for solving one single problem.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the heat dissipation unit of the present invention;

FIG. 2 is a perspective assembled view of the first embodiment of the heat dissipation unit of the present invention;

FIG. 3 is a sectional view of the first embodiment of the heat dissipation unit of the present invention;

FIG. 4 is a top sectional view of a second embodiment of the heat dissipation unit of the present invention;

FIG. 5 is a perspective exploded view of a third embodiment of the heat dissipation unit of the present invention;

FIG. 6 is a top sectional view of a fourth embodiment of the heat dissipation unit of the present invention;

FIG. 7 is a top sectional view of a fifth embodiment of the heat dissipation unit of the present invention; and

FIG. 8 is a sectional view of a sixth embodiment of the heat dissipation unit of the present invention.

### DETAILED DESCRIPTION OF THE PREFERRED EMBODIMENTS

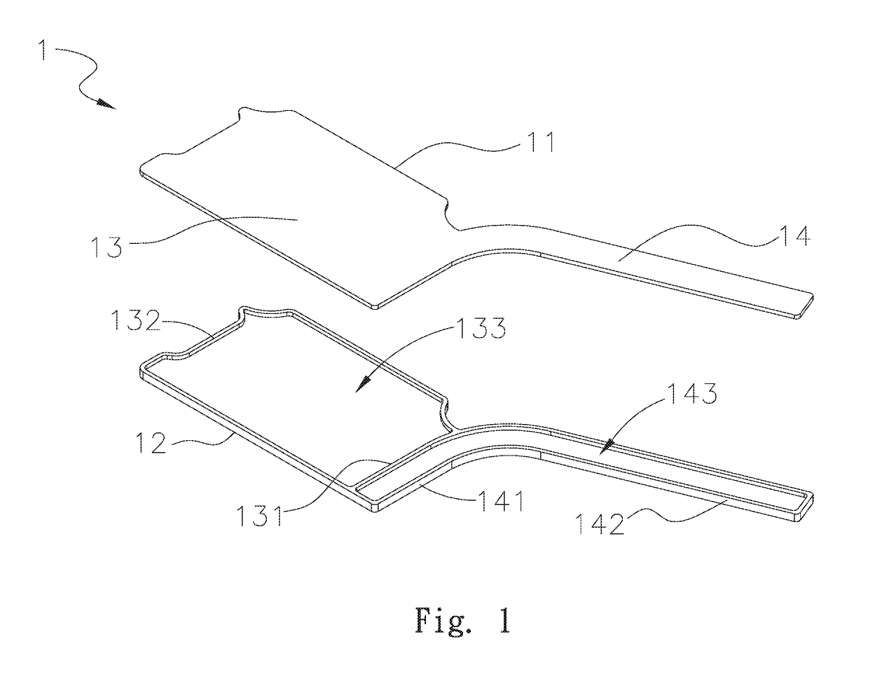

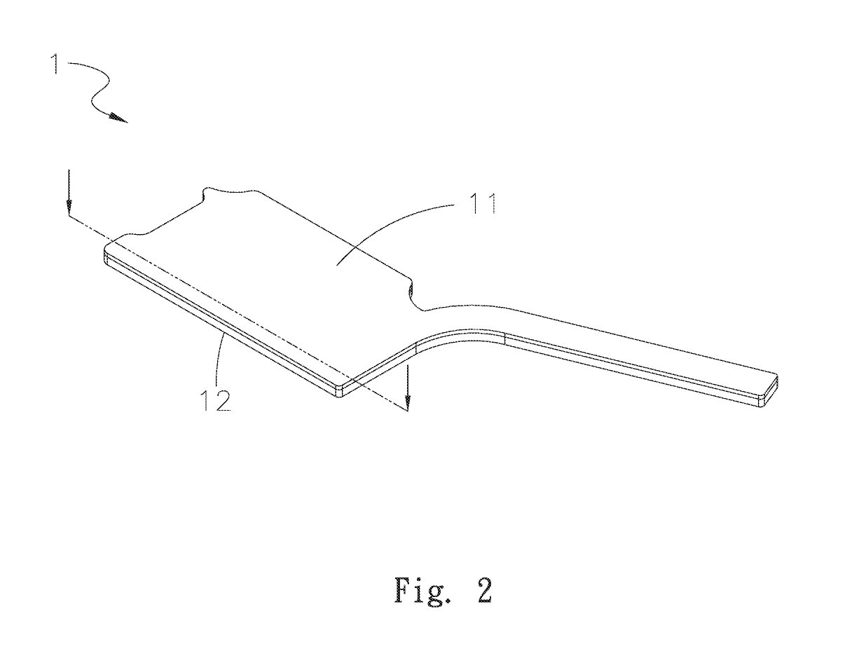

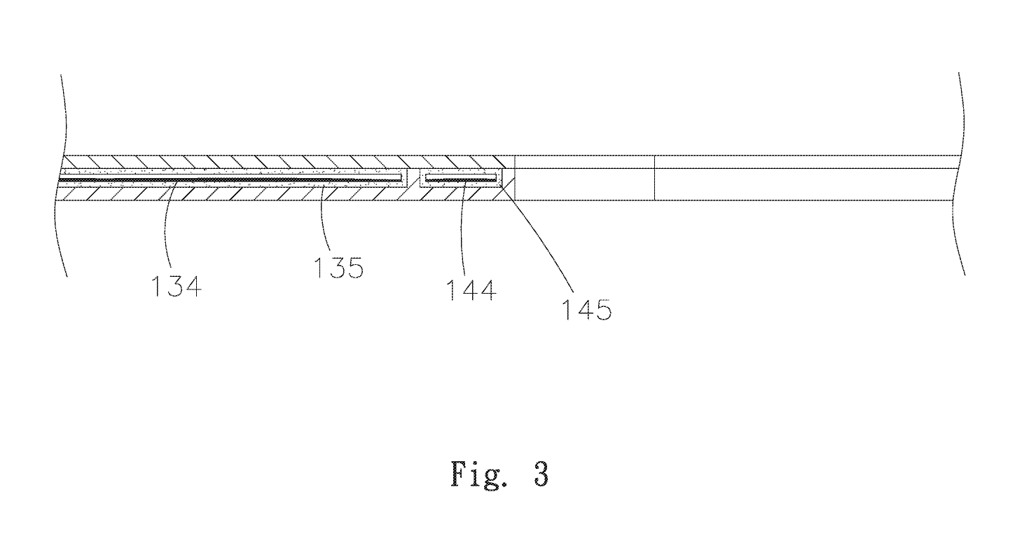

Please refer to FIGS. 1, 2 and 3. FIG. 1 is a perspective exploded view of a first embodiment of the heat dissipation unit of the present invention. FIG. 2 is a perspective assembled view of the first embodiment of the heat dissipation unit of the present invention. FIG. 3 is a sectional view of the first embodiment of the heat dissipation unit of the present invention. According to the first embodiment, the heat dissipation unit of the present invention includes an integrally formed main body 1. The main body 1 has a first plate body 11 and a second plate body 12 correspondingly mated with the first plate body 11 and covered thereby. The main body 1 has a first heat dissipation section 13 and at least one second heat dissipation section 14 connected with the first heat dissipation section 13. In this embodiment, the first heat dissipation section 13 serves as, but not limited to, a vapor chamber structure. In practice, the first heat dissipation section 13 can serve as an equivalent of the vapor chamber structure. The second heat dissipation section 14 serves as, but not limited to, a heat pipe structure. In practice, the second heat dissipation section 14 can serve as an equivalent of the heat pipe.

The first heat dissipation section 13 has a first connection end 131 and a second connection end 132. The first heat dissipation section 13 is formed with a first chamber 133 in which a first working fluid 134 is filled. A first capillary structure 135 is disposed on inner wall of the first chamber 133.

The second heat dissipation section 14 has a heat absorption end 141 and a heat dissipation end 142. The second heat dissipation section 14 is formed with a second chamber 143 in which a second working fluid 144 is filled. A second capillary structure 145 is disposed on inner wall of the second chamber 143. The first and second chambers 133, 143 are defined between the first and second plate bodies 11, 12 (on the same plane) without communicating with each other. The first and second working fluids 134, 144 are selected from a group consisting of pure water, inorganic compound, alcohol group, ketone group, liquid metal, coolant and organic compound.

The first and second capillary structures 135, 145 are selected from a group consisting of mesh bodies, fiber bodies, sintered powder bodies, combinations of mesh bodies and sintered powders, microgroove bodies and a complex combination thereof. The first and second capillary structures 135, 145 also are not connected with each other.

According to the above structural design of the present invention, the main body 1 is an integrally formed structure and the heat absorption end 141 of the second heat dissipation section 14 is connected with the first connection end 131 of the first heat dissipation section 13. The heat dissipation end 142 of the second heat dissipation section 14 extends, but not limited to, in a direction away from the heat absorption end 141. In a modified embodiment, the heat absorption end 141 of the second heat dissipation section 14 is selectively correspondingly connected with the other two sides of the first and second connection ends 131, 132 of the first heat dissipation section 13 (not shown).

When the second plate body 12 of the main body 1 contacts a heat source such as a CPU, an MCU, a graphics processing unit or any other heat generation electronic component or winding (not shown), the heat of the heat source not only is large-area spread and dissipated via the first heat dissipation section 13, but also is transferred to a remote end through the structural design of the second heat dissipation section 14 to achieve remote-end heat conduction and dissipation effect. This improves the shortcoming of the conventional vapor chamber and heat pipe that it is necessary to independently manufacture the vapor chamber and heat pipe at high cost and more manufacturing time is consumed. Accordingly, the present invention can greatly lower the manufacturing cost and achieve both large-area heat dissipation effect and remote-end heat conduction and dissipation effect.

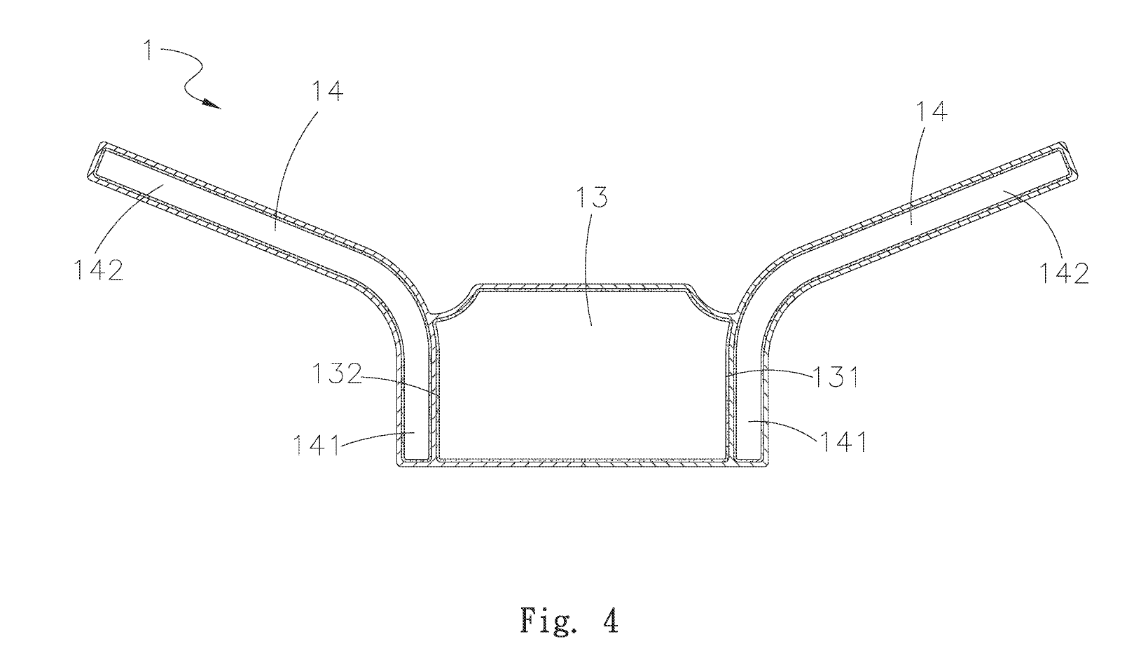

Please now refer to FIG. 4, which is a top sectional view of a second embodiment of the heat dissipation unit of the present invention. The second embodiment is partially identical to the first embodiment in component and relationship between the components and thus will not be repeatedly described hereinafter. The second embodiment is mainly different from the first embodiment in that the first and second ends 131, 132 of the first heat dissipation section 13 are respectively connected with the heat absorption ends 141 of two second heat dissipation sections 14. The heat dissipation ends 142 of the two second heat dissipation sections 14 extend in a direction away from the heat absorption ends 141. In other words, in this embodiment, the main body 1 has two second heat dissipation sections 14 respectively connected with the first and second ends 131, 132 of the first heat dissipation section 13. This can achieve the same effect as aforesaid.

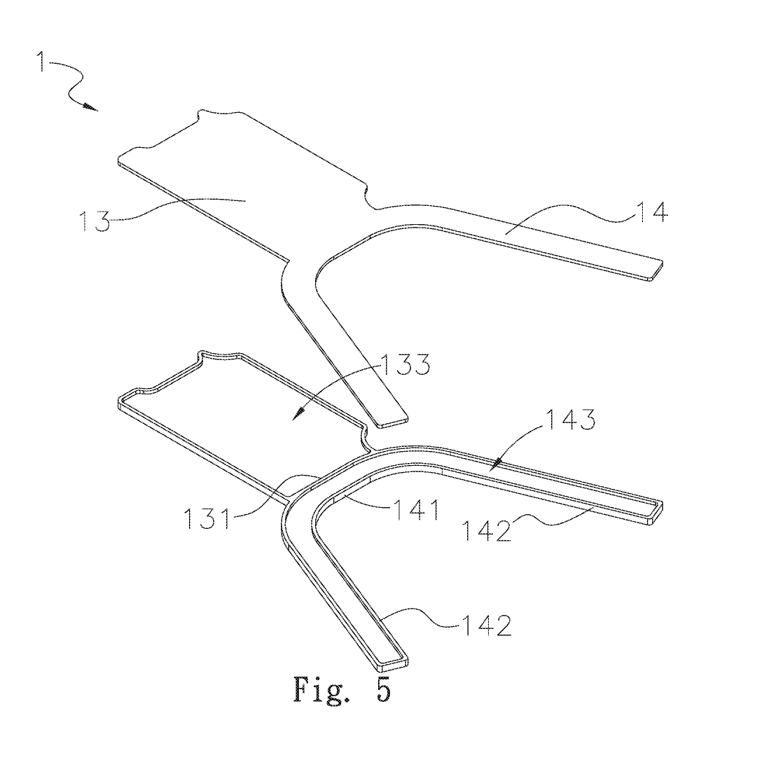

Please now refer to FIG. 5, which is a perspective exploded view of a third embodiment of the heat dissipation unit of the present invention. The third embodiment is partially identical to the first embodiment in component and relationship between the components and thus will not be repeatedly described hereinafter. The third embodiment is mainly different from the first embodiment in that the heat dissipation ends 142 of the second heat dissipation section 14 respectively outward oppositely extend from two ends of the heat absorption end 141. As shown in the drawing, the second heat dissipation section 14 is U-shaped and connected with the first connection section 131 of the first heat dissipation section 13. This can achieve the same effect as aforesaid.

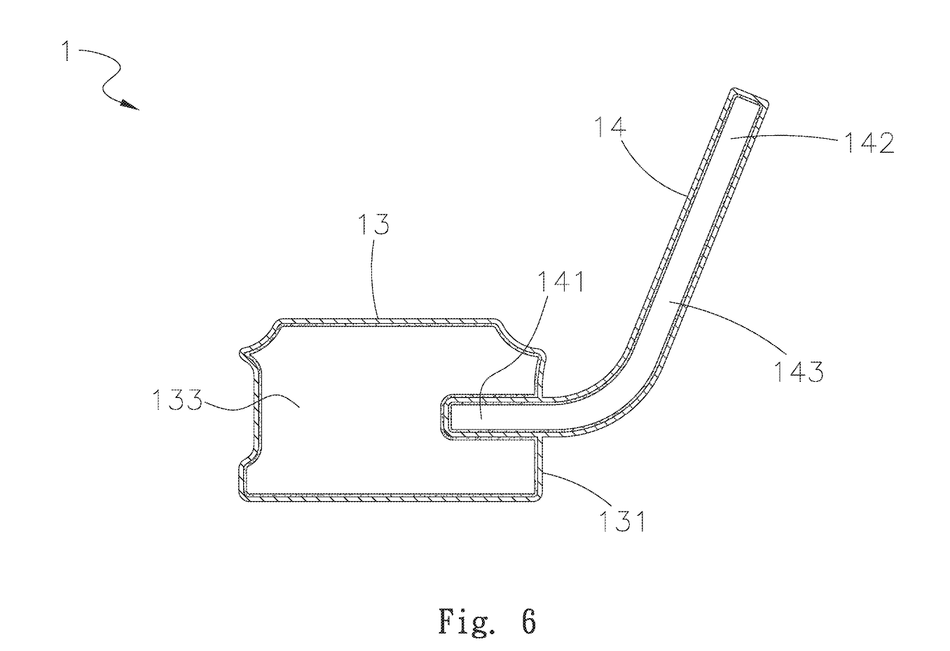

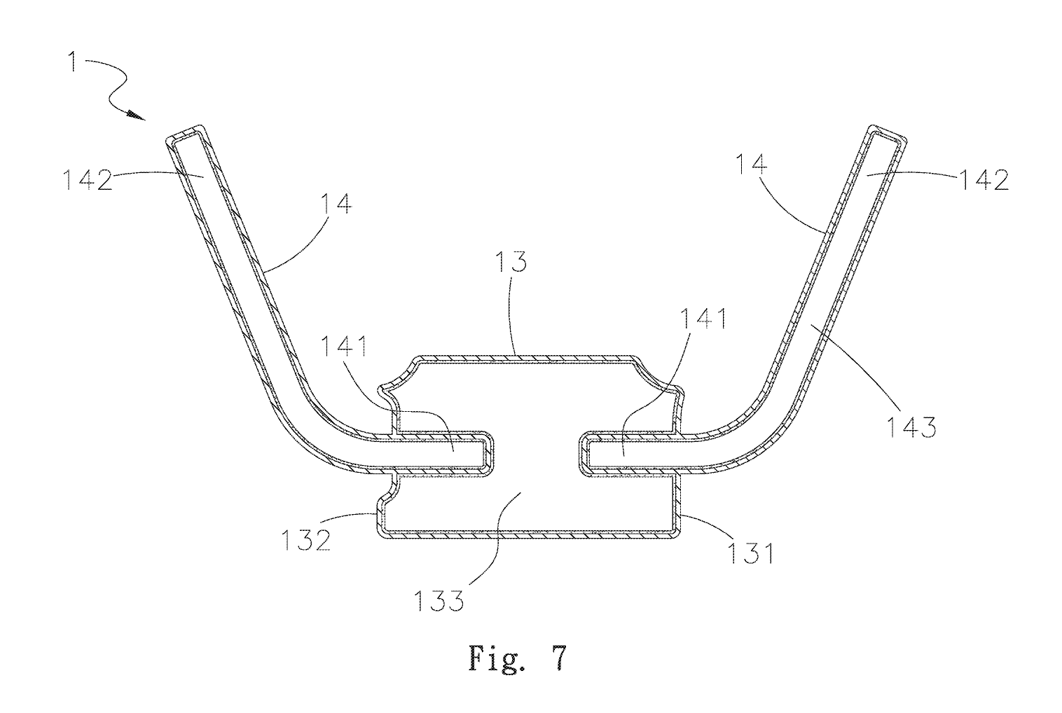

Please now refer to FIG. 6, which is a top sectional view of a fourth embodiment of the heat dissipation unit of the present invention. The third embodiment is partially identical to the first embodiment in component and relationship between the components and thus will not be repeatedly described hereinafter. The fourth embodiment is mainly different from the first embodiment in that the heat absorption end 141 extends from the first connection end 131 into the first chamber 133 and the heat dissipation end 142 extends in a direction away from the heat absorption end 141. In other words, the second chamber 143 is partially disposed in the first chamber 133. In a modified embodiment as shown in FIG. 7, the main body 1 has two second heat dissipation sections 14. The two heat absorption ends 141 of the two second heat dissipation sections 14 respectively extend from the first and second connection ends 131, 132 into the first chamber 133. The two heat dissipation ends 142 respectively extend in a direction away from the heat absorption ends 141. This can achieve the same effect as aforesaid.

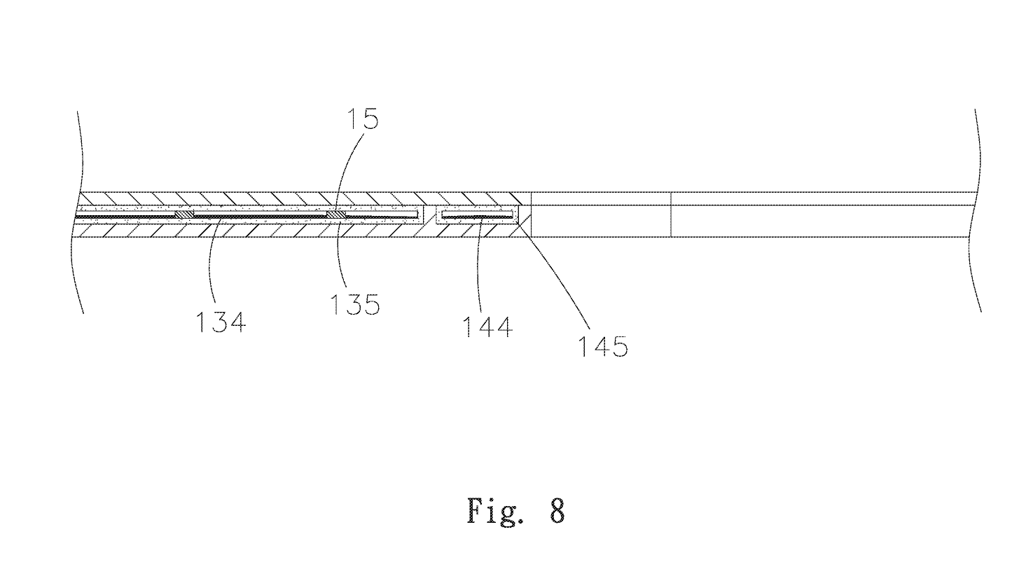

Please now refer to FIG. 8 and supplementally to FIG. 1. FIG. 8 is a sectional view of a sixth embodiment of the heat dissipation unit of the present invention. The sixth embodiment is partially identical to the first embodiment in component and relationship between the components and thus will not be repeatedly described hereinafter. The sixth embodiment is mainly different from the first embodiment in that at least one support structure 15 is disposed in the first chamber 133 of the first heat dissipation section 13. The support structure 15 is selected from a group consisting of copper column, sintered powder column body and annular column body. Two ends of the support structure 15 are respectively connected with the first and second plate bodies 11, 12. When the second plate body 12 is heated, the liquid first working fluid 134 is evaporated into vapor first working fluid 134. The vapor first working fluid 134 will go to the first plate body 11 into contact with the inner wall of the first plate body 11. Then the vapor first working fluid 134 is condensed and converted into the liquid first working fluid 134. Then the support structure 15 will draw the liquid first working fluid 134 back to the second plate body 12.

In conclusion, in comparison with the conventional vapor chamber and heat pipe, the present invention has the following advantages:
1. The manufacturing cost is greatly lowered.
2. The present invention can achieve both large-area heat spreading and dissipation effect and remote-end heat conduction effect.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A heat dissipation unit comprising an integrally formed main body, the main body having a first chamber and at least one second chamber without communicating with each other, a first working fluid being filled in the first chamber, the first chamber being defined as a first heat dissipation section, a second working fluid being filled in the second chamber, the second chamber being defined as a second heat dissipation section, the first heat dissipation section being correspondingly connected with the second heat dissipation section.

2. The heat dissipation unit as claimed in claim 1, wherein an inner wall of the first chamber has a first capillary structure and an inner wall of the second chamber has a second capillary structure, the first and second capillary structures being not connected with each other.

3. The heat dissipation unit as claimed in claim 2, wherein the first and second capillary structures are selected from a group consisting of mesh bodies, fiber bodies, sintered powder bodies, combinations of mesh bodies and sintered powders and microgroove bodies.

4. The heat dissipation unit as claimed in claim 1, wherein the main body further has a first plate body and a second plate body, the second plate body being correspondingly mated with the first plate body and covered thereby, the first and second chambers being defined between the first and second plate bodies.

5. The heat dissipation unit as claimed in claim 4, wherein the first heat dissipation section is a vapor chamber, while the second heat dissipation section is a heat pipe.

6. The heat dissipation unit as claimed in claim 5, wherein the first heat dissipation section has a first connection end and a second connection end and the second heat dissipation section has a heat absorption end and at least one heat dissipation end.

7. The heat dissipation unit as claimed in claim 6, wherein the heat absorption end is connected with the first connection end and the heat dissipation end extends in a direction away from the heat absorption end.

8. The heat dissipation unit as claimed in claim 6, wherein the first and second connection ends of the first heat dissipation section are respectively connected with the heat absorption ends of two second heat dissipation sections, the two heat dissipation ends extends in a direction away from the heat absorption ends.

9. The heat dissipation unit as claimed in claim 6, wherein the heat absorption end extends from the first connection end into the first chamber and the heat dissipation end extends in a direction away from the heat absorption end.

10. The heat dissipation unit as claimed in claim 6, wherein the heat absorption ends of the two second heat dissipation sections respectively extend from the first and second connection ends into the first chamber, the two heat dissipation ends respectively extending in a direction away from the heat absorption ends.

11. The heat dissipation unit as claimed in claim 6, wherein at least one support structure is disposed in the first chamber, the support structure being selected from a group consisting of copper column, sintered powder column body and annular column body, two ends of the support structure being respectively connected with the first and second plate bodies.

12. The heat dissipation unit as claimed in claim 6, wherein the heat dissipation ends respectively outward oppositely extend from two ends of the heat absorption end.
